(19) United States
(12) Patent Application Publication
(10) Pub. No.: US 2010/0073006 A1
(43) Pub. Date: Mar. 25, 2010

(54) Apparatus and Method of Charge Induction for Cable to System Testing

(75) Inventor: Don Alan Gilliland, Rochester, MN (US)

Correspondence Address: IBM CORPORATION;ROCHESTER IP LAW DEPT. 917, 3605 HIGHWAY 52 NORTH, ROCHESTER, MN, 55901-7829, US

(73) Assignee: INTERNATIONAL BUSINESS MACHINES CORPORATION, Armonk, NY (US)

(21) Appl. No.: 12/235,763

(22) Filed: Sep. 23, 2008

(51) Int. Cl. G01R 29/12; H05K 9/00

(52) U.S. Cl. 324/457; 174/377

(57) ABSTRACT

The present invention is directed to an apparatus that minimizes the effects of hand capacitance on a cable, the apparatus also being configured to generate and induce a charge, wherein the charge couples a capacitance to the cable, the capacitance matching a typical capacitance that a hand couples to a cable. The present invention is also generally directed to a method of performing a cable to electronic system electrostatic discharge immunity test.

### BACKGROUND OF THE INVENTION

### Field of the Invention

The present invention generally relates to Electrostatic Discharge (ESD) or the abrupt release of charge from one object (often a person) to another. More specifically the present invention relates an apparatus and method of charge induction for cable to system ESD testing.

### SUMMARY OF THE INVENTION

The present invention is generally directed to an apparatus that minimizes the effects of hand capacitance (e.g., ESD, etc) on a cable while also inducing a charge to the cable, the charge on the cable matching a typical charge on a cable formed by a capacitance when a hand grabs the cable. The present invention is also generally directed to a method of performing a cable to electronic system electrostatic discharge immunity test.

In a first embodiment of the invention, an apparatus to minimize the effects of hand capacitance on a cable comprises a exterior layer, an internal layer having a conduit configured to at least accept a portion of the cable, and a shielding layer substantially surrounding the cable, and a system for inducing an electrical charge to the cable. In another embodiment the apparatus may have two sections, a base and a cover, wherein the electrically non conductive exterior layer, electrically non conductive internal layer, the electrically conductive capacitance shielding layer, and the electrically conductive conduit layer form the base. The cover comprises an exterior layer, an internal layer, and a shielding layer, the cover body being attachable to the base. In another embodiment the shielding layer of the cover contacts the shielding layer of the base. In another embodiment the conduit of the base accepts a lower portion of the cable and the conduit of the cover accepts an upper portion of the cable. In another embodiment the base and the cover are attached together with a hinge. In yet another embodiment a system for inducing an electrical charge to the cable comprises: a conductive gasket, the gasket forming the internal conduit layer and substantially surrounding the cable and being electrically connected to an electrode. In another embodiment the conductive gasket is attached to the base and/or the cover.

In another embodiment of the invention a method of performing a cable to electronic system electrostatic discharge immunity test comprises: placing a shielding apparatus configured to shield the cable from hand capacitance; inducing an electrical charge to the cable, and; inserting the cable to the electronic system. In another embodiment inducing an electrical charge to the cable involves generating the electrical charge and inducing the electrical charge to a conductive gasket substantially surrounding the cable. In yet another embodiment placing the shielding apparatus about the cable further involves: placing the cable into base configured to accept the cable; and installing a cover to the base. In another embodiment inducing a charge to the cable involves generating and inducing a charge, the charge coupling a capacitance to the cable, and wherein the capacitance matching a typical capacitance that a hand couples to a cable.

This and other features, aspects, and advantages will become better understood with reference to the following description, appended claims, and accompanying drawings.

### BRIEF DESCRIPTION OF THE DRAWINGS

So that the manner in which the above recited features of the present invention are attained and can be understood in detail, a more particular description of the invention, briefly summarized above, may be had by reference to the embodiments thereof which are illustrated in the appended drawings.

It is to be noted, however, that the appended drawings illustrate only typical embodiments of this invention and are therefore not to be considered limiting of its scope, for the invention may admit to other equally effective embodiments.

FIG. 1 depicts a schematic view describing the relationship between a human, a cable shielding apparatus, a cable, and an electronic system, according to an embodiment of the present invention.

FIG. 2 depicts an internal cross section view of a cable shielding apparatus according to an embodiment of the present invention.

FIG. 3 depicts another internal cross section view of a cable shielding apparatus according to an embodiment of the present invention.

FIG. 4 depicts an isometric view of the external details of a cable shielding apparatus, according to an embodiment of the present invention.

FIG. 5 depicts another internal cross section view of a cable shielding apparatus according to an embodiment of the present invention.

FIG. 6 depicts an isometric view of a cable shielding apparatus according to an embodiment of the present invention.

FIG. 7 depicts an exploded view of a distal portion of a cable shielding apparatus according to an embodiment of the present invention.

FIG. 8 depicts an alternate view of a cable shielding apparatus according to an embodiment of the present invention.

FIG. 9 depicts an alternate view of the internal features of a cable shielding apparatus according to an embodiment of the present invention.

FIG. 10 depicts an alternate view of the internal features of a cable shielding apparatus according to an embodiment of the present invention.

FIG. 11 depicts a method of performing a cable to electronic system electrostatic discharge immunity test, according to another embodiment of the invention.

### DETAILED DESCRIPTION

IEC Standard 61000-4-2, titled, “Testing and measurement techniques-Electrostatic discharge immunity test,” relates to the immunity requirements and test methods for electrical and electronic equipment subjected to static electricity discharges, from operators directly, and to adjacent objects. It additionally defines ranges of test levels which relate to different environmental and installation conditions and establishes test procedures. The purpose of this standard is to establish a common and reproducible basis for evaluating the performance of electrical and electronic equipment when subjected to electrostatic discharges. In addition, it includes electrostatic discharges which may occur from personnel to objects near vital equipment.

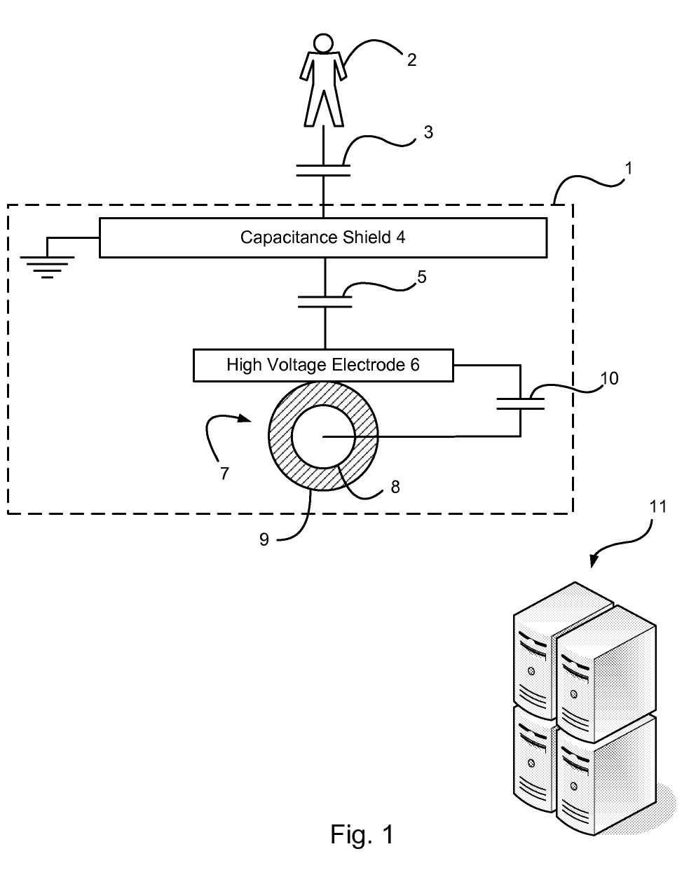

FIG. 1 depicts a schematic view in accordance with a embodiment of the present invention describing the relationship between a human 2, a cable shielding apparatus 1, a cable 7, and an electronic system 11. Shielding apparatus 1 comprises a capacitance shield 4 and a high voltage electrode 6. High voltage electrode 6 is configured to be in electrical contact or otherwise accept cable 7 for at least a length (into the page) that is substantially equal to or greater than the width a hand of the human 2. Cable 7 may comprise an exterior insulator 9 surrounding an electrically conductive material 8. The capacitance shield 4 blocks a capacitance 3 between the human 2 and the cable 7. The capacitance shield 4 also blocks a capacitance 5 between the high voltage electrode 6 and the human 2. Because of capacitance 10, when a charge is applied to high voltage electrode 6, a charge forms upon cable 7. Capacitance 10 is a capacitance that is substantially equal to a typical capacitance from the human 2 to the cable 7 if the shielding apparatus 1 was not present. In other words, capacitance 10 is simulating a typical capacitance that would form when a human would grab the cable. This results in a typical charge being induced to cable 7 that matches a typical charge that is induced when a hand grabs the cable. The hand capacitance to a cable from a human will typically vary. Even the same individual will not typically have the same capacitance each time they grasp the cable. The induced charge (from electrode 6), however, may be tightly controlled and reproducible. After the induced charge is formed onto cable 7, cable 7 is inserted into the electronic system 11, whereby the induced charge is transferred from cable 7 to the electronic system 11. Because the induced charge to the cable is controlled and is reproducible the basis for evaluating the performance of the electronic equipment 11 when subjected to electrostatic discharges is more easily repeatable. In other words, designers may obtain a better understanding of the discharge response levels of the electronic system, when the designer is confident that a particular charge is being induced to the cable in each instance of an electrostatic discharge immunity test.

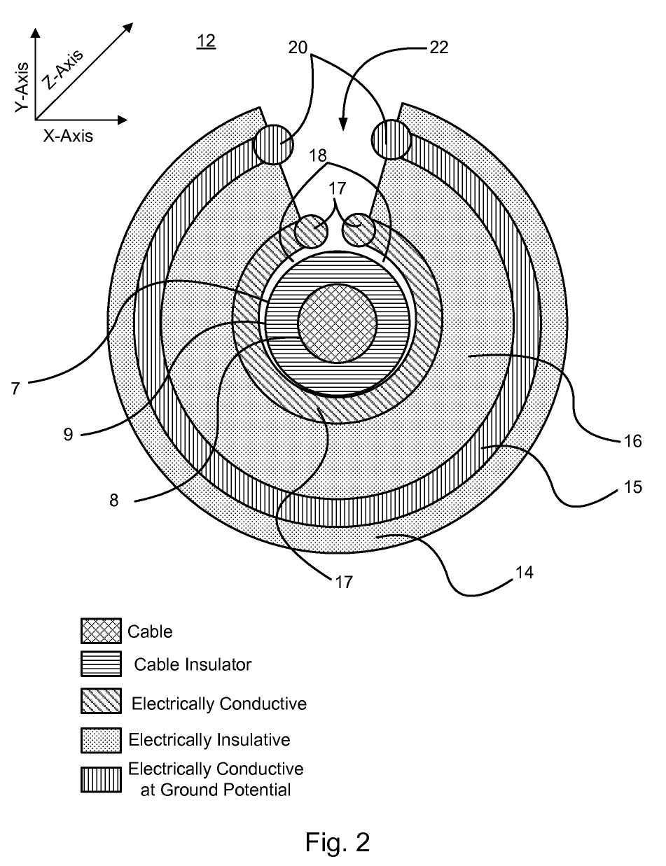

FIG. 2 depicts an internal cross section view of a cable shielding apparatus 12 according to an embodiment of the present invention. Apparatus 12 is utilized in performing an electrostatic discharge immunity test and is configured to minimize the effects of hand capacitance upon cable 7 (i.e., ESD, etc.) and to induce a charge upon cable 7. Apparatus 12 comprises an exterior insulating layer 14, a shielding layer 15, an internal insulating layer 16, and an electrically conductive layer 17. Apparatus 12 utilizes both opening 22, and conduit 18 to accept cable 7. Opening 22 and conduit 18 may extend substantially the full length (z-axis) of apparatus 12. The length of apparatus 12 is at least longer than a width of a human hand. After cable 7 is inserted, apparatus 12 is configured to fully surround cable 7 (i.e., 360 degrees in the x-y plane).

Exterior insulating layer 14 is an electrically insulating layer and may be made from any such electrically insulating material(s) (i.e., plastic, rubber, etc.). Shielding layer 15 is a conductive layer and may be made from any such electrically conductive material(s) (i.e., wire mesh, metallic fabric, metallic fabric over foam, foil on mylar, multiple braided metallic strands, metallic fibers, etc.). Shielding layer 15 is at ground potential, thus the capacitance formed from a hand holding apparatus 12 on cable 7 (i.e., capacitance 3) is substantially eliminated. Internal insulating layer 16 is an electrically insulating layer and may be made from any such electrically insulating material(s) (i.e., plastic, rubber, etc.). Shielding layer 15 may be attached to both internal and exterior insulating layers 16 and 14 respectively by adhesive, heat staking, fastener, or any such equivalent means. Alternatively internal and exterior insulating layers 16 and 14 may be developed utilizing an injection mold (or equivalent), wherein the shielding layer 15 is inserted into the mold prior to forming the two layers. Electrically conductive layer 17 is in electrical contact with one or more electrode(s) (not shown) and is configured to accept and be in contact with cable 7. The electrode(s) transfer an electrical charge to the conductive layer 17, because a capacitance (i.e., capacitance 10) exists between conductive layer 17 and cable 7, a charge is induced upon cable 7. Electrically conductive layer 17 may be made from any such electrically conductive material(s) (i.e., wire mesh, metallic fabric, metallic fabric over foam, foil on mylar, multiple braided metallic strands, metallic fibers, or any such equivalent materials.) Electrically conductive layer 17 may be attached to internal insulating layer 16 by adhesive, heat stake, fastener, or any such equivalent means. Alternatively electrically conductive layer 17 may be developed utilizing an injection mold (or equivalent), wherein the electrically conductive layer 17 is inserted into the mold prior to forming the internal insulating layer 16.

Shielding layer 15 may utilize pads 20 at either distal end of the layer 15. Likewise electrically conductive layer 17 may utilize pads 17 at either distal end of the layer 17. Pads 20 and pads 17 serve as an increase of surface area such that when the apparatus 12 fully surrounds cable 7 (i.e., when opening 22 is closed) the shielding layer 15 and the electrically conductive layer 17 fully surround (i.e., 360 degrees) cable 7. In other words pads 17 and pads 20 ensure the meeting of the distal ends of shielding layer 15 and electrically conductive layer 17 when apparatus 12 fully surrounds cable 7.

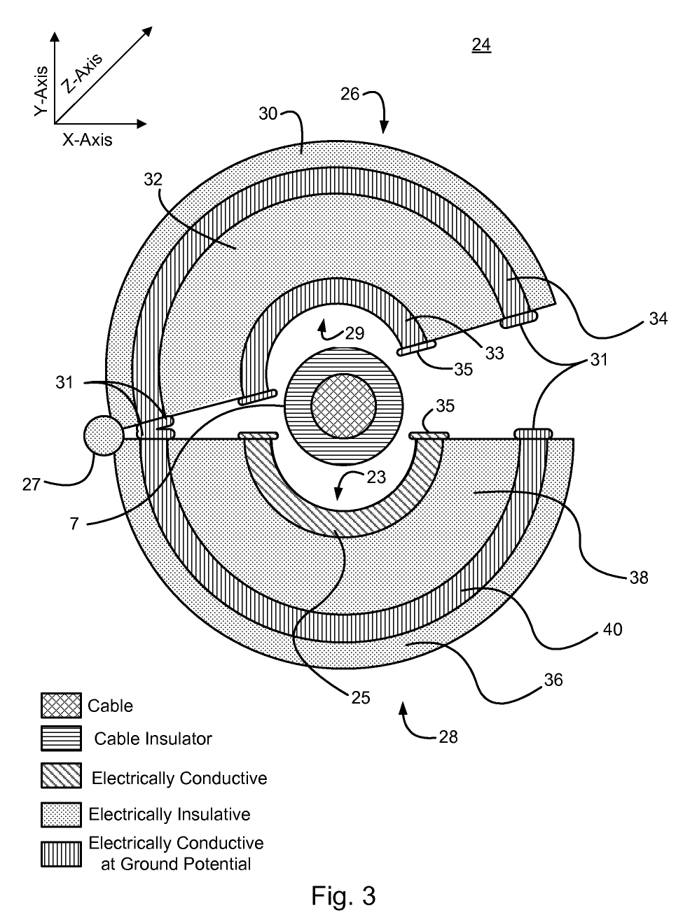

FIG. 3 depicts an internal cross section view of a cable shielding apparatus 24 according to an embodiment of the present invention. Apparatus 24 is also utilized in performing an electrostatic discharge immunity test and is configured to minimize the effects of hand capacitance upon cable 7 (i.e., ESD, etc.) and to induce a charge to cable 7. Apparatus 24 comprises a base 28 and a cover 26. Base 28 comprises an exterior insulating layer 36, a shielding layer 40, an internal insulating layer 38, and an electrically conductive layer 25. Cover 26 comprises an exterior insulating layer 30, a shielding layer 34, an internal insulating layer 32, and an electrically conductive layer 33. Base 28 may be attached to cover 26 with a hinge 27 (i.e., living hinge, ball and socket, pin and socket, pin and groove, interleaved sections, snap together, or any equivalent hinging mechanism). Base 28 utilizes conduit 23 to accept cable 7, while cover 26 utilizes conduit 29 to accept cable 7. Both conduit 29 and conduit 23 extend the full length (z-axis) of cover 26 and base 28 respectively. The length of base 28 and cover 26 is at least longer than a width of a human hand. After cable 7 is inserted, base 28 and cover 26 at least substantially surround (360 degrees in the x-y plane) cable 7.

Exterior insulating layer 30 is an electrically insulating layer and may be made from any such electrically insulating material(s) (i.e., plastic, rubber, etc.). Shielding layer 34 is a conductive layer and may be made from any such electrically conductive material(s) (i.e., wire mesh, metallic fabric, metallic fabric over foam, foil on mylar, multiple braided metallic strands, metallic fibers, or any such equivalent material(s)). Shielding layer 34 is at ground potential, thus the capacitance resulting from a hand holding apparatus 24 on cable 7 (i.e., capacitance 3) is substantially eliminated. Internal insulating layer 32 is an electrically insulating layer and may be made from any such electrically insulating material(s) (i.e., plastic, rubber, etc.). Shielding layer 34 may be attached to both internal and exterior insulating layers 32 and 30 respectively by adhesive, heat stake, fastener, or any such equivalent means. Alternatively internal and exterior insulating layers 32 and 30 may be developed utilizing an injection mold (or equivalent), wherein the shielding layer 34 is inserted into the mold prior to forming the two layers. Either electrically conductive layer 33 or electrically conductive layer 25 (or both) is in electrical contact with one or more electrode(s) (not shown) and is configured to accept and being in contact with cable 7. The electrode(s) transfer an electrical charge to the conductive layer 33 (or conductive layer 25) and because there is a capacitance (i.e., capacitance 10) between the conductive layer 33 and the cable 7 a charge is induced to cable 7. Electrically conductive layer 33 may be made from any such electrically conductive material(s) (i.e., wire mesh, metallic fabric, metallic fabric over foam, foil on mylar, multiple braided metallic strands, metallic fibers, or any such equivalent materials.) Electrically conductive layer 33 may be attached to internal insulating layer 32 by adhesive, heat stake, fastener, or any such equivalent means. Alternatively electrically conductive layer 33 may be developed utilizing an injection mold (or equivalent), wherein the electrically conductive layer 33 is inserted into the mold prior to forming the internal insulating layer 32.

Exterior insulating layer 36 is an electrically insulating layer and may be made from any such electrically insulating material(s) (i.e., plastic, rubber, etc.). Shielding layer 40 is a conductive layer and may be made from any such electrically conductive material(s) (i.e., wire mesh, metallic fabric, metallic fabric over foam, foil on mylar, multiple braided metallic strands, metallic fibers, or any such equivalent material(s)). Shielding layer 40 is at ground potential, thus the capacitance resulting from a hand holding apparatus 24 on cable 7 (i.e., capacitance 3) is substantially eliminated. Internal insulating layer 38 is an electrically insulating layer and may be made from any such electrically insulating material(s) (i.e., plastic, rubber, etc.). Shielding layer 40 may be attached to both internal and exterior insulating layers 38 and 36 respectively by adhesive, heat stake, fastener, or any such equivalent means. Alternatively internal and exterior insulating layers 38 and 36 may be developed utilizing an injection mold (or equivalent), wherein the shielding layer 40 is inserted into the mold prior to forming the two layers. Either electrically conductive layer 33 or electrically conductive layer 25 (or both) is in electrical contact with one or more electrode(s) (not shown) and is configured to accept and being in contact with cable 7. The electrode(s) transfer an electrical charge to the conductive layer 25 (or conductive layer 33) and because there is a capacitance (i.e., capacitance 10) between the conductive layer 25 (or conductive layer 33) and the cable 7, a charge is induced to cable 7. Electrically conductive layer 25 may be made from any such electrically conductive material(s) (i.e., wire mesh, metallic fabric, metallic fabric over foam, foil on mylar, multiple braided metallic strands, metallic fibers, or any such equivalent materials.) Electrically conductive layer 25 may be attached to internal insulating layer 38 by adhesive, heat stake, fastener, or any such equivalent means. Alternatively electrically conductive layer 25 may be developed utilizing an injection mold (or equivalent), wherein the electrically conductive layer 25 is inserted into the mold prior to forming the internal insulating layer 38.

Shielding layer 40 and shielding layer 34 may utilize pads 31 at either distal end of the respective layer. Likewise electrically conductive layer 25 and electrically conductive layer 33 may utilize pads 35 at either distal end of the respective layer. Pads 31 and pads 35 serve as an increase of surface area such that when the cover 26 is closed or otherwise applied to base 28, the cable 7 is fully surrounded. In other words the shielding layer 34 and shielding layer 40 meet when the cover 26 is closed upon the base 28 (i.e., there is a 360 degree in the x-y plan shielding layer surrounding the cable 7) and the electrically conductive layer 25 and the electrically conductive layer 33 meet when the cover 26 is closed upon the base 28 (i.e., there is a 360 degree in the x-y plan electrically conductive layer surrounding the cable 7). Pads 31 and pads 35 ensure the meeting of the distal ends of shielding layers 34 and 40 and electrically conductive layers 25 and 33 when cover 26 is closed upon base 28.

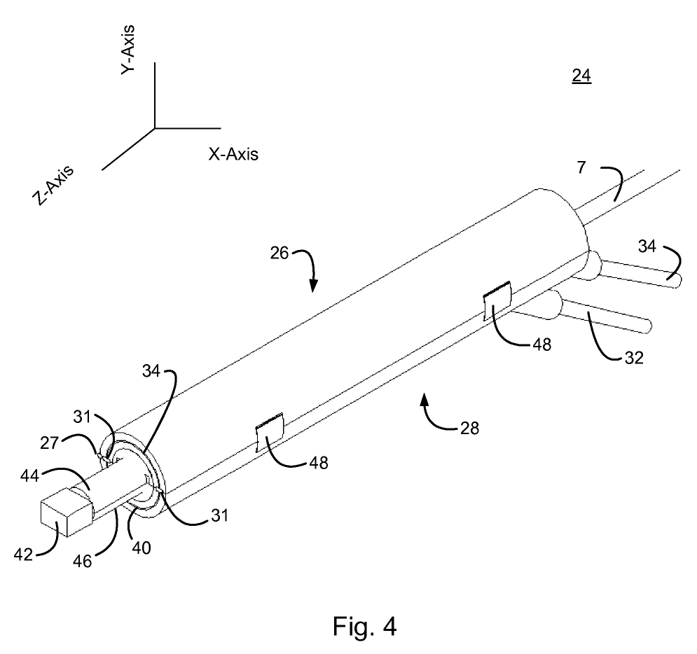

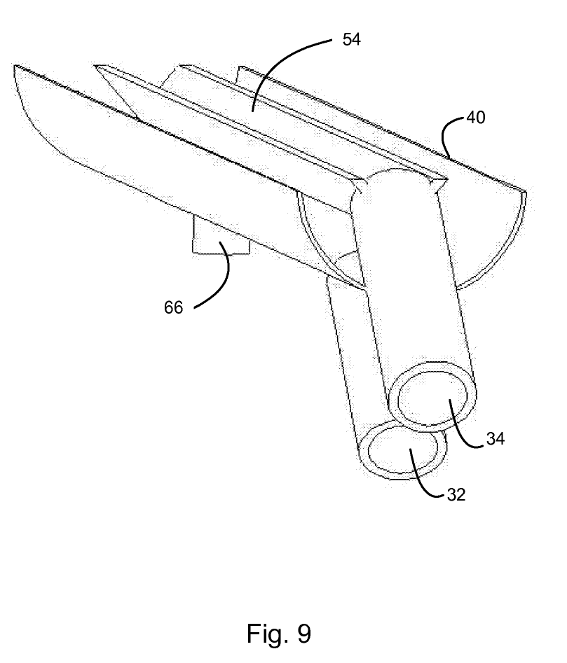

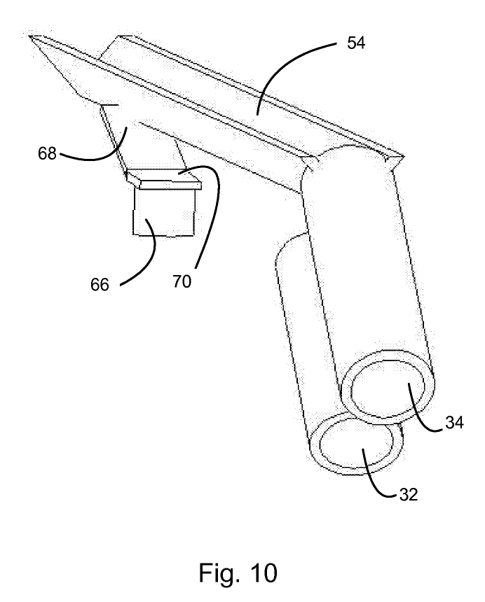

FIG. 4 depicts an isometric view of the external details of cable shielding apparatus 24, according to an embodiment of the present invention. Base 28 and cover 26 are attached together by hinge 27. The base 28 and cover 26, when cover 26 is closed upon base 28, fully surround the cable 7 (360 degrees in the z-axis) and may utilize latch(s) 48 to maintain association. When apparatus 24 fully surrounds cable 7, cable 7 is surrounded (again 360 degree in the z-axis) by a shielding layer comprised of shielding layer 34 and shielding layer 40 in the cover 26 and base 28 respectively. Shielding layer 34 and shielding layer 40 may utilize pads 31 to ensure contact. A small length of cable 7 (or alternatively only a connector 42 upon the cable 7) extends past apparatus 24. Cover 26 may further comprise a tip 44 to aid in the ability to plug connector 42 into, for instance, an electronic system 11. Likewise, base 28 may also further comprise a tip 46 to aid in the ability to plug connector 42. Apparatus 24 also comprises electrodes 32 and 34 utilized to generate an electrical current to the electrically conductive layer 33 and/or 25 respectively. An internal view of electrodes in relationship to the internal electrically conductive layer is shown FIG. 9 and FIG. 10 and described infra.

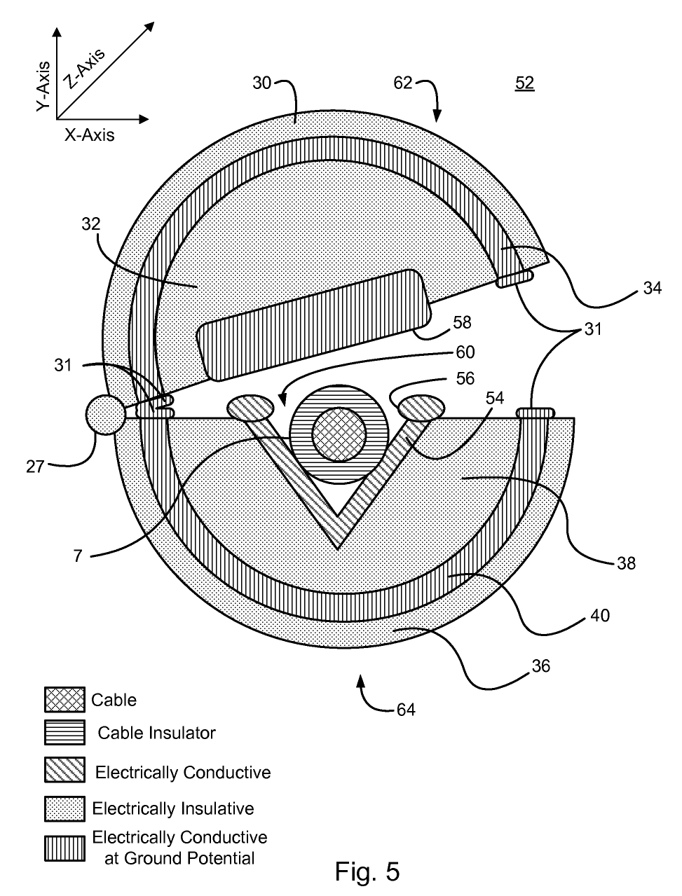

FIG. 5 depicts an internal cross section view of a cable shielding apparatus 52 according to an embodiment of the present invention. Apparatus 52 is also utilized in performing an electrostatic discharge immunity test and is configured to minimize the effects of hand capacitance upon cable 7 (i.e., ESD, etc.) and to induce a charge to cable 7. Apparatus 52 comprises a base 64 and a cover 62. Base 64 comprises an exterior insulating layer 36, a shielding layer 40, an internal insulating layer 38, and a voltage inducing layer 54. Cover 62 comprises an exterior insulating layer 30, a shielding layer 34, an internal insulating layer 32, and an electrically conductive layer 58. Base 64 may be attached to cover 62 with a hinge 27. Base 64 utilizes conduit 60 to accept cable 7. Conduit 60 extends the full length (z-axis) of base 64. The length of base 64 and cover 62 is at least longer than a width of a human hand. After cable 7 is inserted, base 28 and cover 26 at least substantially surround (360 degrees in the x-y plane) cable 7.

Voltage inducing layer 54 is in electrical contact with one or more electrode(s) (not shown) and is configured to accept and being in contact with cable 7. The electrode(s) transfer an electrical charge to voltage inducing layer 54, and because there is a capacitance (i.e., capacitance 10) between the voltage inducing layer 54 and cable 7, a charge is induced to cable 7. Voltage inducing layer 54 may be made from any such electrically conductive material(s) (i.e., wire mesh, metallic fabric, metallic fabric over foam, foil on mylar, multiple braided metallic strands, metallic fibers, or any such equivalent materials.) Voltage inducing layer 54 may be attached to internal insulating layer 38 by adhesive, heat stake, fastener, or any such equivalent means. Alternatively voltage inducing layer 54 may be developed utilizing an injection mold (or equivalent), wherein the voltage inducing layer 54 is inserted into the mold prior to forming the internal insulating layer 38.

Electrically conductive layer 58 is configured to come into electrical contact with voltage inducing layer 54, thereby fully surrounding (360 degrees in the x-y plane) cable 7. The electrode(s) transfer an electrical current to voltage inducing layer 54 (and thereby electrically conductive layer 58) and a charge is induced to cable 7. Electrically conductive layer 58 may be made from any such electrically conductive material(s) (i.e., wire mesh, metallic fabric, metallic fabric over foam, foil on mylar, multiple braided metallic strands, metallic fibers, or any such equivalent materials.) Electrically conductive layer 58 may be attached to internal insulating layer 32 by adhesive, heat stake, fastener, or any such equivalent means. Alternatively electrically conductive layer 58 may be developed utilizing an injection mold (or equivalent), wherein the electrically conductive layer 58 is inserted into the mold prior to forming the internal insulating layer 32.

Voltage inducing layer 54 may utilize pads 56 at either distal end of the respective layer. Pads 56 serve as an increase of surface area such that when the cover 62 is closed or otherwise applied to base 64, the cable 7 is fully surrounded. In other words the electrically conductive layer 58 and the voltage inducing layer 54 meet when the cover 62 is closed upon the base 64 (i.e., there is a 360 degree in the x-y plane electrically conductive layer surrounding the cable 7).

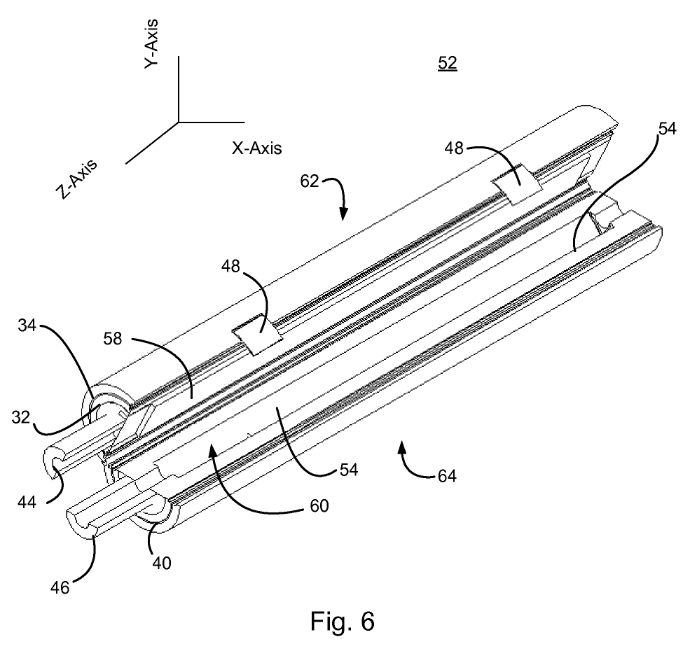

FIG. 6 depicts an isometric view of apparatus 52 according to an embodiment of the present invention. Apparatus comprised a base 64 and cover 62. The base 64 and cover 62 fully surround the cable 7 (360 degrees in the x-y plane) when cover 62 is applied to base 64. Apparatus 52 may utilize latch(s) 48 to maintain the association of cover 62 to base 64 when the cover 62 is closed upon base 64. When apparatus 52 fully surrounds cable 7, cable 7 is surrounded (again 360 degrees about the x-y plane) by a shielding layer comprised of shielding layer 34 and shielding layer 40 in the cover 62 and base 64 respectively. Shielding layer 34 and shielding layer 40 may utilize pads 31 (not shown in FIG. 6) to ensure contact. Cover 62 may further comprise a tip 44 to aid in the ability to plug connector 42 (not shown) into, for instance, an electronic system 11. Likewise, base 64 may also further comprise a tip 46 to aid in the ability to plug connector 42. Apparatus 52 also comprises electrodes 32 and 34 (not shown in FIG. 6) utilized to generate an electrical current to voltage inducing layer 54. When cover 62 is closed upon base 64, conductive layer 58 comes into electrical contact with voltage inducing layer 54. An internal view of electrodes in relationship to the internal electrically conductive layer and voltage inducing layer is shown FIG. 9 and FIG. 10 and described infra.

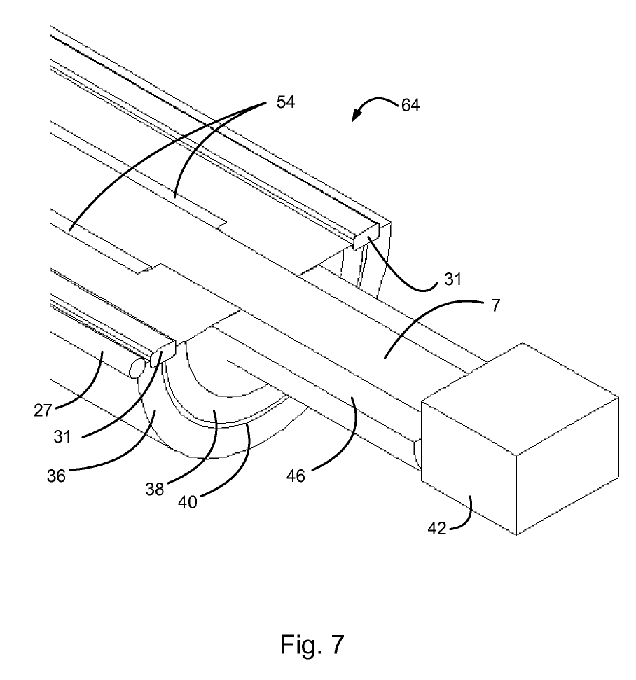

FIG. 7 depicts an exploded view of a distal portion of the base 64 of the cable shielding apparatus 52 according to an embodiment of the present invention. Base 64 accepts cable 7 in conduit 60. Cable 7 may be retained within base 64 by a retention mechanism (i.e., snap fit, adhesive or other tacky substance, or any other known or equivalent retention mechanism). The retention mechanism may be located within tip 46, within the opposing distal end of apparatus 52 (i.e., opposite end of tip 46), or in other interior locations of base 64. A small length of cable 7 (or alternatively only the connector 42) extends outwardly from the distal end of base 64. Base 64 may comprise a tip 46 to aid in the ability to plug connector 42 into, for instance, an electronic system 11.

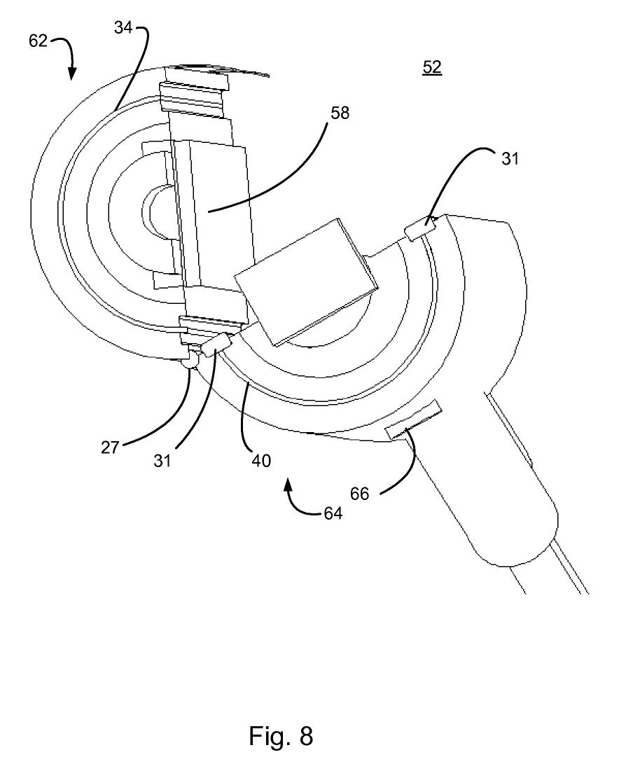

FIG. 8 depicts an alternate view of a cable shielding apparatus 52 according to an embodiment of the present invention. In the present embodiment, apparatus 52 utilizes a trigger 66. Trigger 66 may be located upon cover 62 and/or base 66. Trigger 66 is an electrical switch that controls when electrical current/charge may be introduced by electrode(s) 32 and/or 34 to voltage inducing layer 54. Trigger 66 may be configured such that electrical current only is allowed to travel through voltage inducing layer 54, thereby inducing a charge upon cable 7, if trigger 66 is depressed. Essentially trigger 66 acts as a safety mechanism allowing a charge to be induced to cable 7 only when apparatus 52 is being properly utilized (i.e., a hand is around apparatus 52 and depressing trigger 66). Releasing trigger 66 allows the induced charge, to return to ground potential.

FIG. 9 depicts an alternate view of the internal features of a cable shielding apparatus 52 according to an embodiment of the present invention. Electrode 34 is in electrical contact with voltage inducing layer 54 and provides layer 54 with electrical current whereby a charge is resultantly induced to cable 7 (not shown). Electrode 32 is in electrical contact with shielding layer 40. Electrode 32 and shielding layer 40 are at ground potential.

FIG. 10 depicts an alternate view of the internal features of a cable shielding apparatus 52 according to an embodiment of the present invention. Trigger 66 may utilize extension 68 and extension 70. Under nominal conditions (i.e., when trigger is not depressed) extension 68 is in electrical contact with voltage inducing layer 54, and extension 70 is in electrical contact with shielding layer 40. Therefore the charge passing through voltage inducing layer is passed to ground. When trigger 66 is depressed extension 68 is no longer in electrical contact with voltage inducing layer 54.

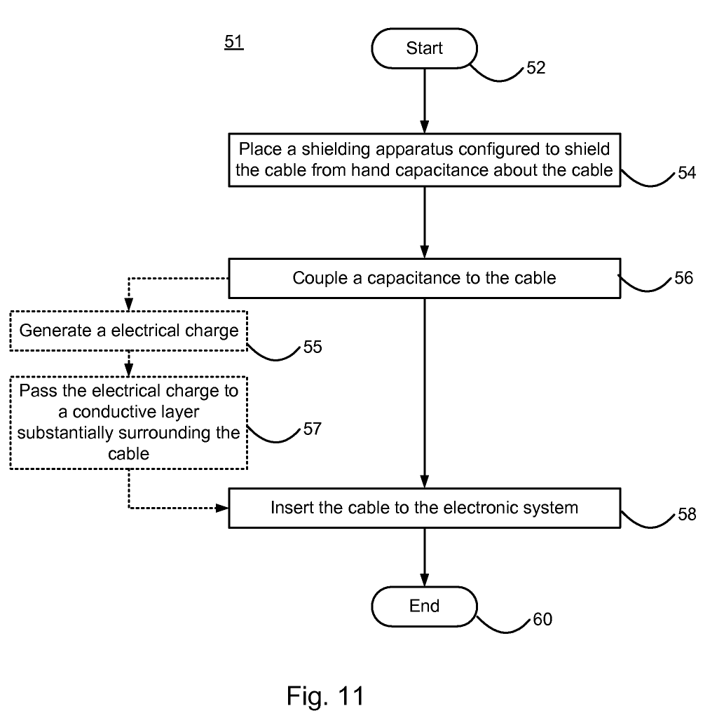

FIG. 11 depicts a method 51 of performing a cable to electronic system electrostatic discharge immunity test, according to another embodiment of the invention. Method 51 starts at block 52. A shielding apparatus configured to shield the cable from hand capacitance is placed about cable 7 (block 54). An electrical charge is passed through a conductive layer surrounding the cable thereby inducing a charge to cable 7 (block 56). Cable 7 is then inserted to the electronic system (block 58). Method 51 ends at block 60.

In an alternative embodiment of the method, the apparatus configured to shield the cable is further configured to provide for inducing the electrical charge to the cable. In another embodiment, inducing an electrical charge to the cable involves generating a electrical charge (block 55) and passing the electrical charge to a conductive layer (block 57) substantially surrounding the cable. An opposite charge therefore is induced to cable 7.

In an alternative embodiment of the method, placing the shielding apparatus about the cable further involves: placing the cable into a conduit of the base of the apparatus, wherein the conduit is configured to accept the cable; installing a cover to the base.

The accompanying figures and this description depicted and described embodiments of the present invention, and features and components thereof. Those skilled in the art will appreciate that any particular mechanism nomenclature used in this description was merely for convenience, and thus the invention should not be limited to use solely in any specific application identified and/or implied by such nomenclature. Thus, the mechanisms executed to implement the embodiments of the invention could have been referred to by other meaningful nomenclature. For example the word “couple” is used interchangeably with “formed” in the situation as described above where a capacitance is formed/coupled to the cable. Therefore, it is desired that the embodiments described herein be considered in all respects as illustrative, not restrictive, and that reference be made to the appended claims for determining the scope of the invention.

The invention claimed is:

1. An cable shielding apparatus comprising:
an electrically non conductive exterior layer, an electrically non conductive internal layer, a electrically conductive capacitance shielding layer at ground potential separating the exterior layer and the internal layer, a electrically conductive conduit layer connected to a electrode, the electrode configured to selectively transfer an electrical charge to the electrically conductive conduit layer.

2. The apparatus of claim 1 wherein the cable shielding apparatus further comprises:
a cable extending through the conduit, and wherein when selectively transferred, the charge from electrode to the electrically conductive conduit layer thereby induces an opposite charge to the cable.

3. The apparatus of claim 2 wherein the electrically non conductive exterior layer, electrically non conductive internal layer, the electrically conductive capacitance shielding layer, and the electrically conductive conduit layer form a base.

4. The apparatus of claim 3 where the base is configured to accept a cover, the cover comprising:
an electrically non conductive exterior layer, an electrically non conductive internal layer, and electrically conductive capacitance shielding layer separating the exterior layer and the internal layer, and an electrically conductive conduit layer extending through the cover.

5. The apparatus of claim 4 further comprising:
a cable contacting and laying within the electrically conductive conduit layer.

6. The apparatus of claim 4 wherein the induced charge is substantially similar to a typical charge formed between a human and a cable when the human touches the cable.

7. The apparatus of claim 6 wherein the shielding layer of the cover contacts the shielding layer of the base.

8. The apparatus of claim 7 wherein the conduit of the base accepts a lower portion of the cable and the conduit of the cover accepts an upper portion of the cable.

9. The apparatus of claim 8 wherein the base and the cover are attached together with a hinge.

10. The apparatus of claim 4 wherein the electrically conductive conduit layer of the cover is in electrical contact with the electrically conductive conduit layer of the base when the cover is closed upon the base.

11. The apparatus of claim 10 wherein the electrically conductive conduit layer of the cover and the electrically conductive conduit layer of the base is fabric over foam gasket.

12. The apparatus of claim 10 further comprising:
a first electrode in electrical contact with electrically conductive conduit layer, and a second electrode at ground potential in electrical contact with the electrically conductive capacitance shielding layer.

13. The apparatus of claim 12 wherein the electrically conductive capacitance shielding layer of the cover body contacts the electrically conductive capacitance shielding layer of the base.

14. The apparatus of claim 13 further comprising a trigger configured to allow electrical current to conduit the electrically conductive conduit layer if the trigger is depressed.

15. An discharge immunity test apparatus comprising:
a base comprising an electrical non conductive exterior layer, an electrical non conductive internal layer having a conduit being substantially lined with a conductive gasket, the conductive gasket being configured to at least accept a portion of the cable, and an electrically conductive shielding layer separating the internal and exterior non conductive layers, the shielding layer surrounding at least a portion of the cable;
a cover comprising an electrical non conductive exterior layer, an electrical non conductive internal layer having a conduit being substantially lined with a conductive gasket, the conductive gasket being configured to at least accept a portion of the cable, and an electrically conductive shielding layer separating the internal and exterior non conductive layers, the shielding layer surrounding at least a portion of the cable;
means for passing an electrical charge to the conductive gasket of either the base or the cover, and;
wherein the shielding layer of the base contacts the shielding layer of the cover, and wherein the conductive gasket of the base contacts the conductive gasket of the cover.

16. The apparatus of claim 15 wherein the base further comprises a trigger configured to allow the electrical charge to the conductive gasket if the trigger is depressed.

17. A method of performing a cable to electronic system electrostatic discharge immunity test comprising:
placing a shielding apparatus configured to shield the cable from hand capacitance about the cable;
inducing an electrical charge to the cable, and;
inserting the cable to the electronic system.

18. The method of claim 17 wherein the apparatus configured to shield the cable is further configured to provide for the inducing the electrical charge to the cable.

19. The method of claim 18 wherein inducing an electrical charge to the cable involves generating a electrical charge and passing the electrical charge though a conductive layer substantially surrounding the cable thereby inducing the charge to the cable.

20. The method of claim 19 wherein placing the shielding apparatus about the cable further comprises:
placing the cable into base configured to accept the cable, the base comprising an electrical non conductive exterior layer, an electrical non conductive internal layer having a conduit being substantially lined with the conductive gasket, the conductive gasket being configured to at least accept a portion of the cable, and an electrically conductive shielding layer separating the internal and exterior non conductive layers, the shielding layer surrounding at least a portion of the cable;
installing a cover body to the base, the cover comprising an electrical non conductive exterior layer, an electrical non conductive internal layer having a conduit being substantially lined with the gasket, the conductive gasket being configured to at least accept a portion of the cable, and an electrically conductive shielding layer separating the internal and exterior non conductive layers, the shielding layer surrounding at least a portion of the cable.
